(19) United States
(12) Patent Application Publication
(10) Pub. No.: US 2016/0254316 A1
(43) Pub. Date: Sep. 1, 2016

(54) LED DISPLAY MASK AND LED DISPLAY

(71) Applicant: UNILUMIN GROUP CO., LTD., Shenzhen, Guangdong (CN)

(72) Inventors: Guijiao GUO, Shenzhen (CN); Jinfeng HE, Shenzhen (CN); Dan HU, Shenzhen (CN)

(73) Assignee: UNILUMIN GROUP CO., LTD, Schenzhen (CN)

(21) Appl. No.: 14/420,876

(22) PCT Filed: Nov. 3, 2014
(86) PCT No.: PCT/CN2014/090157

§ 371 Date: Feb. 10, 2015

(30) Foreign Application Priority Data
Aug. 14, 2014 (CN) 201420459180.5

(51) Int. Cl. H01L 27/15

(52) U.S. Cl. CPC H01L 27/156

(57) ABSTRACT

An LED display mask and an LED display are provided. The LED display includes at least two first frame strips and at least two second frame strips which are orthogonal to each other and form a rectangular mesh body. The rectangular mesh body is fixed to a bottom case of an LED module and has at least two unclosed sides. The tail ends of the frame strips orthogonal to the unclosed sides exceed the outside frame strips parallel to the unclosed sides. The LED display mask and the LED display solve the problem that the existing adjacent masks on the LED display bulge at the junctions because of unmatched dimensions or thermal expansion, resulting in black shadows and dark areas on the display. With the present invention the excessive parts can be easily cut when adjacent masks extend mutually to form bulges without affecting the characteristics of the display.

### CROSS-REFERENCE TO RELATED PATENT APPLICATIONS

This application is a U.S. National Phase Application under 35 U.S.C. §371 of International Patent Application No. PCT/CN2014/090157, filed Nov. 3, 2014, and claims the benefit of Chinese Patent Application No. 20140459180.5 filed Aug. 14, 2014, all of which are incorporated herein by reference in their entirety.

### FIELD OF THE INVENTION

The present invention relates to the field of LED displays; in particular, to an LED display mask and an LED display.

### DESCRIPTION OF THE RELATED ART

At present, during installation and manufacturing of LED displays, cases of LED modules are needed to be adhered with masks that mainly conduct the functions of fixing the LED modules, blocking sunlight and preventing sunlight from affecting the light effect. Problems like black shadows and dark areas that affect the display effect of the display usually appear after the existing displays are covered with the masks. Analysis shows that the problems may be caused by: 1. when the modules are separately assembled, the adjacent masks do not fit with each other and therefore are mutually extruded to bulge; 2. when modules are placed in a single case, the masks of the adjacent modules are mutually extruded to bulge; 3. when the LED displays are joined, the masks of the joined adjacent cases are mutually extruded to bulge; 4. the masks are too large and therefore are mutually extruded to bulge; and 5. after the display turns on, the bulbs generate heat, resulting in that the masks bulge due to thermal expansion. In order to avoid the masks on the displays bulging and affecting the display effect and flatness of the display as much as possible, it is necessary to provide a display mask and an LED display that can solve the above problems well.

### BRIEF SUMMARY OF THE INVENTION

The technical problem to be solved in the present invention is the provision of an LED display mask and an LED display that solves the problem of existing adjacent masks on the LED display that bulge at the junctions because of unmatched dimension or thermal expansion, resulting in black shadows and dark areas on the display.

To solve the above technical problem, the present invention employs the following technical solution: An LED display mask comprises at least two first frame strips and at least two second frame strips; the first frame strips and the second frame strips are orthogonal to each other and form a rectangular mesh body; and the rectangular mesh body is fixed at the bottom case of an LED module.

The rectangular mesh body has at least two unclosed sides, wherein the tail ends of the frame strips orthogonal to the unclosed sides exceed the frame strips on the outside and parallel to the unclosed sides.

Furthermore, all of the four rectangular sides of the rectangular mesh body are unclosed sides.

Furthermore, the rectangular mesh body has two opposite closed sides.

Furthermore, the first frame strips and the second frame strips are made from PC engineering plastic.

Furthermore, a 3M adhesive layer is disposed between the rectangular mesh body and the bottom case of the LED module.

The present invention also provides another technical solution:

An LED display comprises an LED module and several LED display masks installed on the bottom case of the LED module. Each LED display mask comprises at least two first frame strips and at least two second frame strips; the first frame strips and the second frame strips are orthogonal to each other in order to form a rectangular mesh body; and the rectangular mesh body is fixed at the bottom case of the LED module.

The rectangular mesh body has at least two unclosed sides, wherein the tail ends of the frame strips orthogonal to the unclosed sides exceed the outside frame strips parallel to the unclosed sides.

Furthermore, each mesh of the rectangular mesh body is adaptively embedded with an LED bulb. Furthermore, each mesh of the rectangular mesh body is embedded with more than two LED bulbs at the same time.

Furthermore, each mesh of the rectangular mesh body is embedded with two LED bulbs arranged vertically at the same time; and the rectangular mesh body has two opposite closed sides.

The present invention has the following beneficial effects: distinguishing from the existing LED displays with problems of poor display effects such as black shadows and dark areas on the displays because of bulging of the display masks the present invention provides an LED display mask. The rectangular mesh body has at least two unclosed rectangular sides, and the tail ends of the frame strips orthogonal to the unclosed sides exceed the outside frame strips parallel to the unclosed sides. With the unclosed sides, the display masks with corresponding unclosed sides can be flexibly selected during installation of the display mask. When adjacent display masks swell due to unmatched dimensions or thermal expansion and the bulging positions collide with the display adhesive, the excessive parts touching the adhesive can be easily cut, and then the display is still flat after being equipped with the mask. The LED display consisting of the above-mentioned LED display masks can avoid having the masks extrude and damage the LED bulbs due to serious bulging, and also ensure that the LED display is free from the effects of the bulging masks and does not generate black shadows and dark areas.

### BRIEF DESCRIPTION OF SEVERAL VIEWS OF THE ATTACHED DRAWINGS

These and other features and advantages of the present invention will become more readily appreciated when considered in connection with the following detailed description and appended drawings, wherein like designations denote like elements in the various views, and wherein:

FIG. 1 is a structural view of an LED display mask in the prior art.

FIG. 2 is a structural view of an LED display mask according to an embodiment of the present invention.

FIG. 3 is a structural view of the composition of an LED display mask of the embodiment of the present invention.

FIG. 4 is a structural view of an LED mask with four lamps and one frame of an

LED display in the embodiment of the present invention.

FIG. 5 is a structural view of an LED mask with multiple lamps and one frame of an LED display in the embodiment of the present invention.

FIG. 6 is a structural view of joint of multiple LED display mask on a single module in the LED display in the embodiment of the present invention.

FIG. 7 is a drawing showing a protuberant contact edge caused by the unmatched size of t two prior art LED masks.

### DESCRIPTION OF THE REFERENCE NUMBERS

1-First frame strip; 2-Second-frame strip; 3-Rectangular mesh body; 4-LED module; 5-LED bulb; 6-outside frame strips; 7-four open rectangular unclosed sides; 8-ends of the frame strips; 9-bottom case; 10-bulges.

### DETAILED DESCRIPTION OF THE INVENTION

The technical content, objectives and effects of the present invention are described in detail with reference to embodiments and the attached drawings.

A key concept of the present invention lies in that: a rectangular mesh body forming an LED display with orthogonally arranged first and second frame strips has at least two unclosed rectangular sides with excessive parts of the strips that can be easily cut off when the adjacent masks form bulges due to extrusion or thermal expansion, without changing the characteristics of the display.

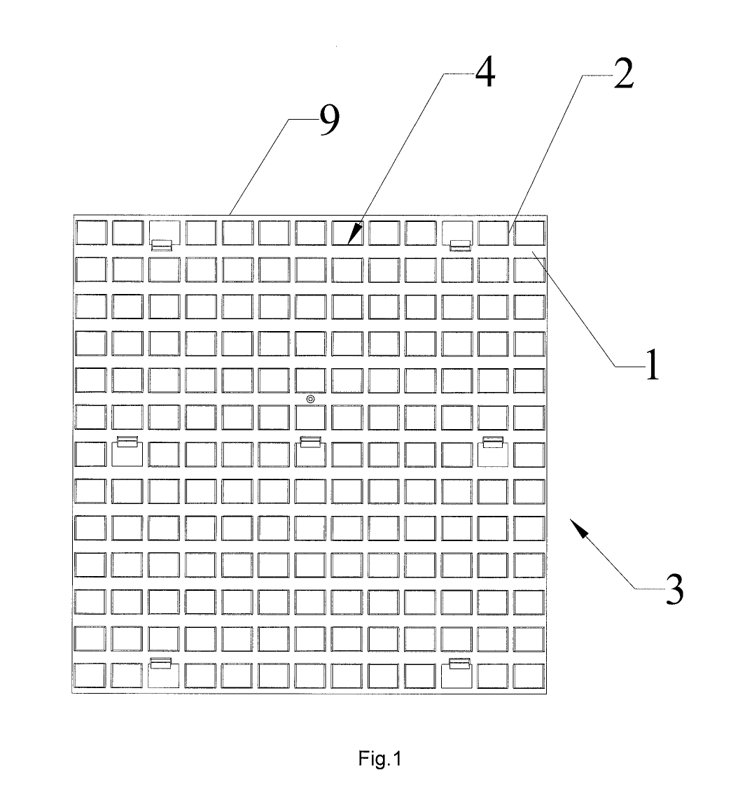

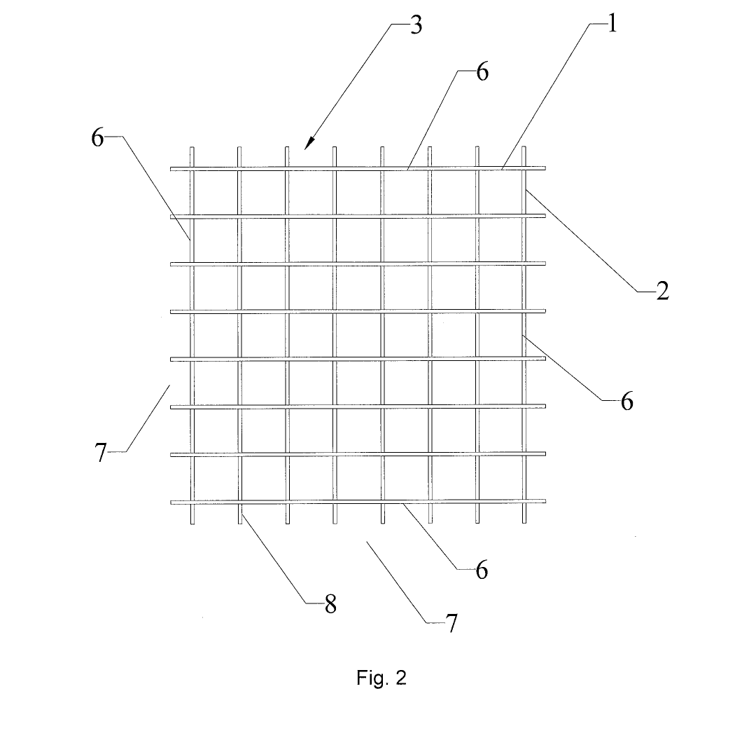

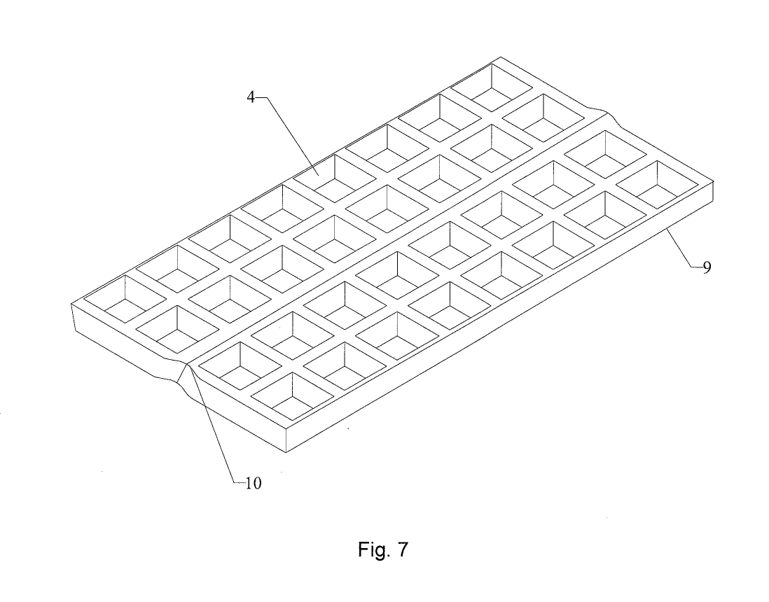

Referring to FIGS. 1-3 an LED display mask of the present invention comprises at least two first frame strips 1 and at least two second frame strips 2; the first frame strips 1 and the second frame strips 2 are orthogonal with respect to each other in order to form a rectangular mesh body 3; where the rectangular mesh body 3 is fixed on the bottom case 9 (FIG. 7) of the LED module 4.

The rectangular mesh body 3 has at least two unclosed sides 7, wherein the tail ends 8 of the frame strips orthogonal to the unclosed sides 7 exceed the outside frame strips 6 on the outside and parallel to the unclosed sides.

From the above description, it can be known that, the LED display mask provided in the present invention has a rectangular mesh body 3 with at least two unclosed rectangular sides 7, wherein the ends 8 of the frame strips 1 and 2 orthogonal to the unclosed sides 7 exceed the outside frame strips 6 parallel to the enclosed sides. With the unclosed sides, the display masks with corresponding unclosed sides can be flexibly selected and placed next to each other during installation of the display mask. When adjacent display masks swell due to unmatched dimensions or thermal expansion and the bulging positions collide with the display adhesive, the excessive parts 8 touching the adhesive can be easily cut, so that the display is still flat after being equipped with the mask, thus keeping the masks from extending and damaging the LED bulbs 5 due to serious bulging, and also ensuring that the LED display is free from the effects of bulging and does not generate black shadows and dark areas.

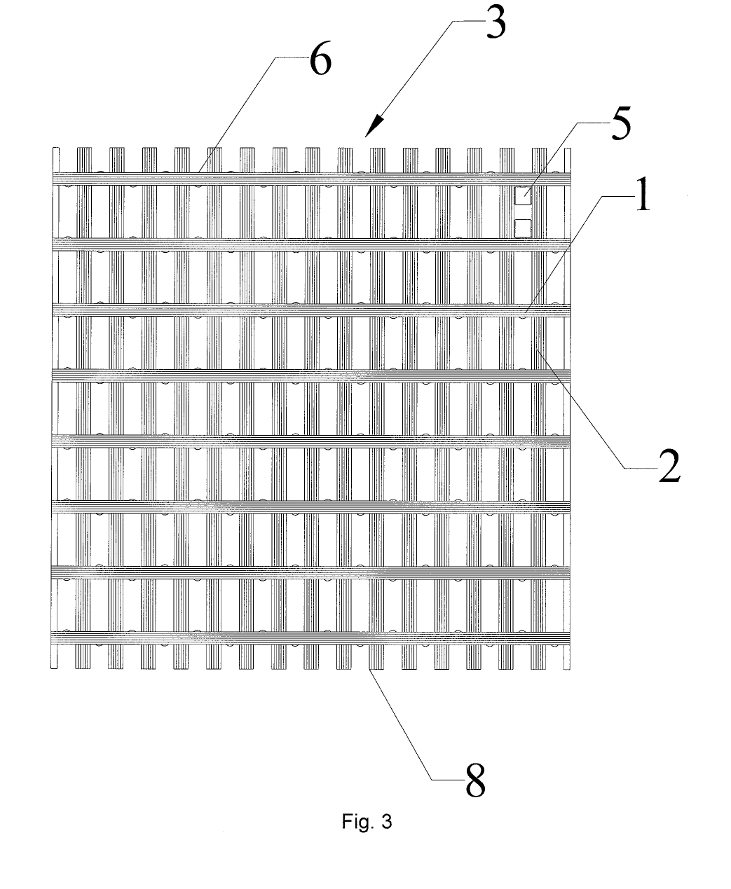

The rectangular edge, corresponding to the edge position of the display, of the rectangular mesh body 3 that is preferably installed at the edge position of the display, is unclosed. The sizes of the cells formed on the rectangular mesh body 3 are designed according to the pixel spacing of the bulbs on the LED display. The options include one-lamp-one-frame configuration, two-lamps-one-frame configuration, four-lamps-one-frame configuration or multi-lamp-one-frame configuration. The bulbs and cell edges are clamped and fixed in a stuck-point way. See FIG. 3.

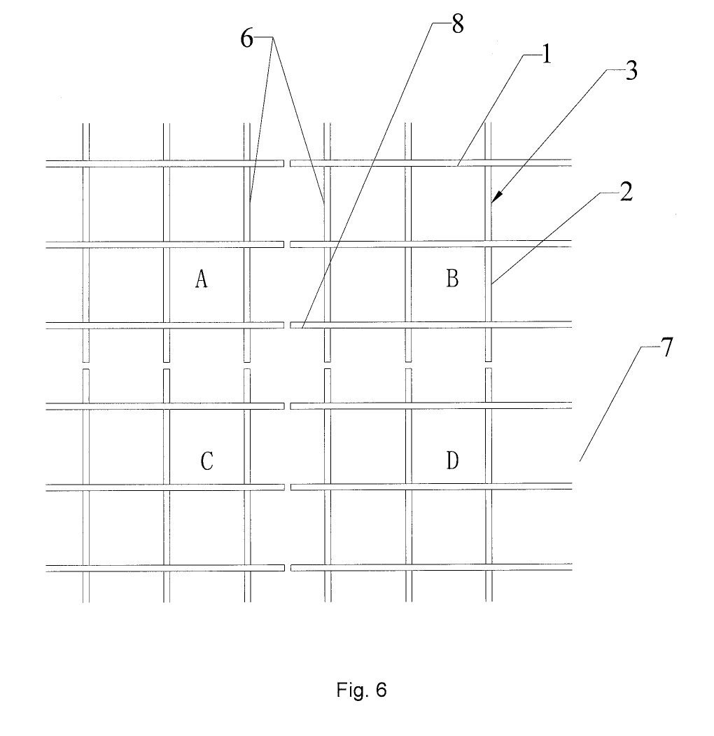

Referring to FIG. 6, it can be seen that each of four single LED display masks (A, B, C & D) covers a small area, and one module of an LED display may be comprised of more than 9 LED display masks, but the large-scale LED display is formed by joining multiple modules or cases joined by multiple modules. Then, at junctions of adjacent LED masks, it is easy to form bulges 10 due to extrusion or expansion between unmatched parts, and the bulging frame strips may easily touch the adhesive, which is disposed between the rectangular mesh body 3 and the bottom case 9 of the LED module. If the frame strips touching the adhesive expand too much, damage will be caused to the nearby bulbs 6. Even if the bulbs are not damaged, the LED display will generate black spots or dark areas because the bulging part of the frame touches the adhesive, thus affecting the characteristics of the LED display. The unclosed rectangular edge structure 7 of the LED display mask of the present invention brings convenience to manufacturers because they can directly and easily cut off the excessive part 8 of the bulging mask during trimming, so the display can be flat. For details, see junctions among the LED display masks in FIG. 6. The junctions among the displays are flat and matched with one another and have no effect on the entire LED display mask. For the existing or prior art entirely closed display mask, it is difficult to cut the mask parts because of the mutually connected frame strips.

It should be noted that the LED display mask with at least two unclosed sides provided by the present invention can also make the LED display flat and free from bulging after installation, without cutting. During processing of the LED display mask, it is set that the excessive part of the tail end 8 of the frame strip parallel to the unclosed edge 7 is equal to or smaller than half of each side length of a cell on the rectangular mesh body. The LED display mask employing this structure can be fixed on the case of the LED module 4 in a joining way during installation, while the adjacent LED display masks are joined so as to reserve a certain clearance at junctions, which can also ensure flatness of the LED display without manual cutting of the excessive part.

Furthermore, all the four rectangular sides of the rectangular mesh body 3 are shown with unclosed sides 7. However, from the above description, it can be known that the rectangular mesh body 3 of the LED display mask structure without four unclosed rectangular sides can be preferably be disposed on the non-edge positions of the LED display. Furthermore, the rectangular mesh body 3 has been shown with two opposite closed sides. In particular, from the above description, it can be known that two of the rectangular sides on the rectangular mesh body 3 as shown in FIG. 3 are unclosed sides. The rectangular mesh body 4 of such a structure is applicable to the display which is structured in such a way as to have two lamps and one frame or structured as a transverse strip type single module, and the two lamp bulbs in the display structure with two lamps and one frame are arranged in parallel along the extension direction of the rectangular closed sides of the rectangular mesh body 3.

Furthermore, the first frame strips 1 and the second frame strips 2 may be made from PC engineering plastic. The LED display mask may be comprised of PC engineering plastic frame strips, which has the advantages of flexibility and high heat resistance.

Furthermore, the adhesive is a 3M adhesive layer disposed between the rectangular mesh body 3 and the bottom case 9 of the LED module 4. The rectangular mesh body can also be screwed to the bottom case 9 of the LED module 4 or fixed by combining the 3M adhesive and screwing.

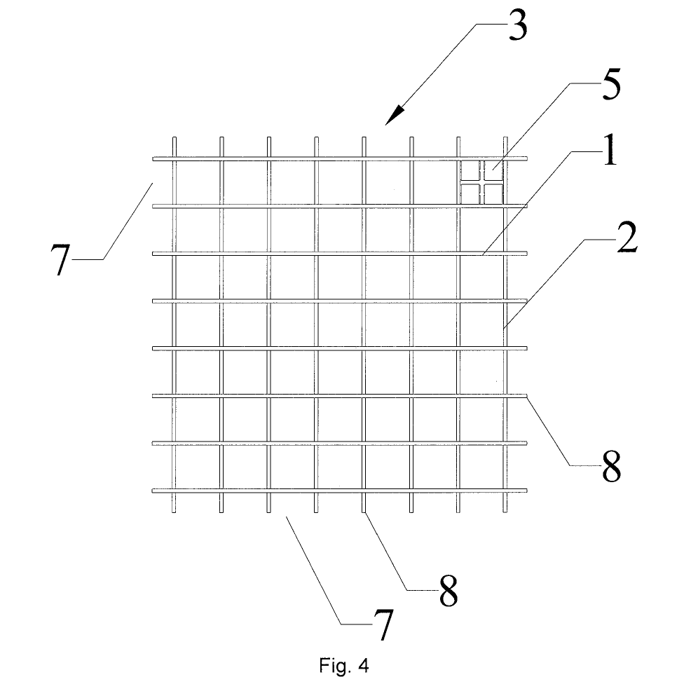

Referring to FIGS. 4-6, the present invention also provides another technical solution: In particular, an LED display comprises an LED module 4 and several LED display masks installed on the bottom of the case of the LED module 4; each LED display mask comprises at least two first frame strips 1 and at least two second frame strips 2; the first frame strips 1 and the second frame strips 2 are orthogonal to each other in order to form a rectangular mesh body 3; and the rectangular mesh body 3 is fixed to the bottom case 9 of the LED module 4.

The rectangular mesh body 3 has at least two unclosed sides 7, wherein the tail ends 8 of the frame strips orthogonal to the unclosed sides exceed the frame strips on the outside and parallel to the unclosed sides.

From the above description it can be known that the adjacent display masks on the LED display do not form bulges 10 (FIG. 7) at the junctions, but are embedded on the bottom case 9 of the LED module 4 without clearance. As a result, the masks will not extend to the bulbs 5 due to serious expansion, cause damage to the bulbs and affect the display characteristics of the LED display, so the problems of black shadows and dark areas never occur.

Furthermore, each mesh of the rectangular mesh body 3 is adaptively embedded with the LED bulb 5. Furthermore, each mesh of the rectangular mesh body 3 may be embedded with more than two LED bulbs 5. Still further, each mesh of the rectangular mesh body 3 may be embedded with two LED bulbs 5 arranged vertically; and the rectangular mesh body 3 may have two opposite closed sides.

Referring to FIG. 4, the Embodiment 1 of the present invention is as follows:

The cells on the LED display mask can be embedded with four LED bulbs 5 at the same time, and the rectangular mesh body 3 may have four unclosed sides 7. The tail ends 8 of the frame strips orthogonal to the unclosed sides exceed the outside frame strips 6 parallel to the unclosed sides to form the LED display mask with four open rectangular sides 7.

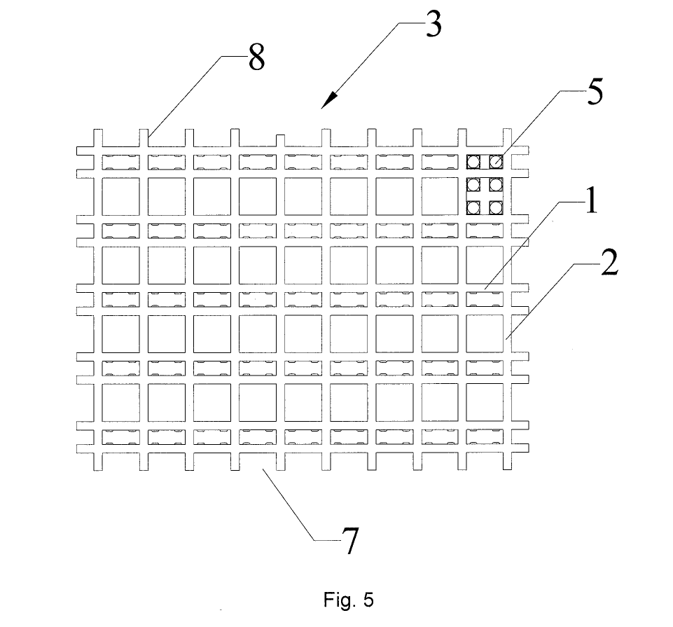

Referring to FIG. 5, the Embodiment 2 of the present invention is as follows:

The first frame strips 1 and the second frame strips 2 on the LED display are orthogonally arranged to form two meshes of different structures at an interval; the meshes in one row can be embedded with two LED bulbs 5 at the same time, and meshes in another row can be embedded with four LED bulbs 5 at the same time. This structure is a multi-lamp-one-frame structure. Moreover, the tail ends 8 of the frame strips orthogonal to the unclosed sides 7 exceed the outside of another frame strip parallel to the unclosed edge, forming an LED display mask with four open rectangular 7 sides.

In conclusion, the present invention provides an LED display mask and an LED display. By the present invention, the problem of the bulging mask extending or extruding to the bulbs and damaging the bulbs can be solved. The LED display will not be affected by the bulging mask so as to avoid having black shadows and dark areas. Furthermore, LED display masks of different structures that are matched with the clearness among the LED bulbs on the display can be selected and installed according to the actual installation demand to meet the demand of the actual production. Finally, the display masks made from PC engineering plastic have advantages of flexibility and high heat resistance.

The above-mentioned descriptions are only two embodiments of the present invention, and are not intended to limit the present invention. Within the spirit and principle of the present invention, any modification of the equivalent structure or direct or indirect application in other related technical fields all fall within the protection scope of the present invention.

1. An LED display mask, comprising at least two first frame strips and at least two second frame strips; said first frame strips and said second frame strips are orthogonal to each other and form a rectangular mesh body; said rectangular mesh body is fixed to a bottom case of an LED module; said rectangular mesh body has at least two unclosed sides, wherein tail ends of the frame strips vertical to the unclosed sides exceed the outside frame strips parallel to the unclosed sides.

2. The LED display mask according to claim 1, characterized in that four rectangular sides of the rectangular mesh body are unclosed sides.

3. The LED display mask according to claim 1, characterized in that the rectangular mesh body has two opposite closed sides.

4. The LED display mask according to claim 1, characterized in that the first frame strips and the second frame strips are made from PC engineering plastic.

5. The LED display mask according to claim 1, characterized in that a 3M adhesive layer is disposed between the rectangular mesh body and the LED module.

6. An LED display, comprising an LED module and several LED display masks installed on the bottom case of the LED module; each LED display mask comprises at least two first frame strips and at least two second frame strips; said the first frame strips and said second frame strips are vertical to each and form an rectangular mesh body; and said rectangular mesh body is fixed to the bottom case of the LED module;
said rectangular mesh body has at least two unclosed sides, wherein tail ends of the frame strips vertical to the unclosed sides exceed the frame strips on the outside and parallel to the unclosed sides.

7. The LED display according to claim 6, characterized in that each mesh of the rectangular mesh body is adaptively embedded with an LED bulb.

8. The LED display according to claim 6, characterized in that each mesh of the rectangular mesh body is adaptively embedded with more than two LED bulb at the same time.

9. The LED display mask according to claim 6, characterized in that each mesh of said rectangular mesh body can be embedded with two vertically arranged LED bulbs at the same time; and said rectangular mesh body has two opposite closed sides.
